(19) United States
(12) Patent Application Publication
(10) Pub. No.: US 2024/0143886 A1
(43) Pub. Date: May 2, 2024

(54) METHOD OF CORRECTING LAYOUT FOR SEMICONDUCTOR PROCESS USING MACHINE LEARNING, METHOD OF MANUFACTURING SEMICONDUCTOR DEVICE USING THE SAME, AND LAYOUT CORRECTION SYSTEM PERFORMING THE SAME

(71) Applicant: SAMSUNG ELECTRONICS CO., LTD., SUWON-SI (KR)

(72) Inventors: Kyeonghwan Kang, Suwon-si (KR); Jungmin Kim, Suwon-si (KR); Hungbae Ahn, Suwon-si (KR)

(21) Appl. No.: 18/342,011

(22) Filed: Jun. 27, 2023

(30) Foreign Application Priority Data
Oct. 31, 2022 (KR) 10-2022-0142426

(51) Int. Cl. G06F 30/392; G06T 7/00; G06T 7/13; G06T 7/73

(52) U.S. Cl. CPC G06F 30/392; G06T 7/0006; G06T 7/001; G06T 7/13; G06T 7/73; G06T 2207/20081; G06T 2207/30148

(57) ABSTRACT

a method of correcting a layout for semiconductor process includes receiving a design layout including a layout pattern for the semiconductor process to form a process pattern of a semiconductor device, where the design layout comprises a pixel-based image associated with the layout pattern and edge information associated with the layout pattern; performing a first layout correction operation on the design layout using a first machine learning model that takes the pixel-based image as input; performing a second layout correction operation on the design layout using a second machine learning model different from the first machine learning model that takes the edge information as input; and obtaining a corrected design layout including a corrected layout pattern corresponding to the layout pattern based on a result of the first layout correction operation and a result of the second layout correction operation.

### CROSS-REFERENCE TO RELATED APPLICATION

This application claims priority under 35 USC § 119 to Korean Patent Application No. 10-2022-0142426, filed on Oct. 31, 2022, in the Korean Intellectual Property Office (KIPO), the disclosure of which is incorporated by reference herein in its entirety.

### BACKGROUND

Embodiments of the present disclosure relate generally to semiconductor integrated circuits, and more particularly to correcting layouts for semiconductor process using machine learning.

Fabrication of semiconductors may involve a combination of various processes such as etching, deposition, plantation, growth, implanting, and the like. Etching may be performed by forming photoresist patterns on the surface of an object to be etched and then removing the uncovered portions of the object using chemical materials, gases, plasmas, ion beams, lasers, or other ablating means.

During the etching process, process deviations may occur due to various factors, such as characteristics of the etching process or characteristics of the semiconductor patterns formed. In some cases, process deviations may be corrected by modifying or changing the layouts of the semiconductor patterns.

In the fabrication of highly integrated semiconductor devices, the number of patterns included in a semiconductor layout significantly increases as space on the semiconductor is utilized more efficiently and the semiconductor process is miniaturized. Accordingly, designing modifications to the layout of the semiconductor patterns to compensate for process deviations may become increasingly difficult.

### SUMMARY

At least one example embodiment of the present disclosure provides a method of correcting a layout for semiconductor process using machine learning capable of efficiently compensating for process deviations.

At least one example embodiment of the present disclosure provides a method of manufacturing a semiconductor device using the method of correcting the layout.

At least one example embodiment of the present disclosure provides a layout correction system performing the method of correcting the layout.

According to example embodiments, a method of correcting a layout for semiconductor process includes receiving a design layout including a layout pattern for the semiconductor process to form a process pattern of a semiconductor device, where the design layout comprises a pixel-based image associated with the layout pattern and edge information associated with the layout pattern; performing a first layout correction operation on the design layout using a first machine learning model that takes the pixel-based image as input; performing a second layout correction operation on the design layout using a second machine learning model different from the first machine learning model that takes the edge information as input; and obtaining a corrected design layout including a corrected layout pattern corresponding to the layout pattern based on a result of the first layout correction operation and a result of the second layout correction operation.

According to example embodiments, a method of manufacturing a semiconductor device includes obtaining a design layout including a layout pattern for semiconductor process to form a process pattern of the semiconductor device forming a corrected design layout by correcting the design layout; fabricating a photomask based on the corrected design layout; and forming the process pattern on a substrate using the photomask. Forming the corrected design layout includes receiving the design layout; performing a first layout correction operation on the design layout using a first machine learning model; performing a second layout correction operation on the design layout using a second machine learning model different from the first machine learning model; and obtaining the corrected design layout including a corrected layout pattern corresponding to the layout pattern based on a result of the first layout correction operation and a result of the second layout correction operation.

According to example embodiments, a layout correction system includes at least one processor; and a non-transitory computer readable medium configured to store program code executed by the at least one processor to form a corrected design layout by correcting a design layout, the design layout including a layout pattern for semiconductor process to form a process pattern of a semiconductor device. The at least one processor is configured, by executing the program code to receive the design layout; to perform a first layout correction operation on the design layout using a first machine learning model, wherein the first layout correction operation comprises a shift correction; to perform a second layout correction operation on the design layout using a second machine learning model different from the first machine learning model, wherein the second layout correction operation comprises a segment correction; and to obtain the corrected design layout including a corrected layout pattern corresponding to the layout pattern based on a result of the first layout correction operation and a result of the second layout correction operation.

In the method of correcting the layout for semiconductor process, the method of manufacturing a semiconductor device, and the layout correction system according to example embodiments, the corrected design layout may be obtained using two machine learning models that are different from each other. For example, the corrected design layout may be obtained or generated by correcting the layout pattern using two different machine learning models alternately and repetitively. Accordingly, various possible errors (e.g., shift errors, segment errors, etc.) may be efficiently corrected or compensated substantially simultaneously or concurrently, and the accuracy of correction may be increased or enhanced.

### BRIEF DESCRIPTION OF THE DRAWINGS

Illustrative, non-limiting example embodiments will be more clearly understood from the following detailed description taken in conjunction with the accompanying drawings. Embodiments of the present disclosure relate to semiconductor process, and more specifically to correcting layouts for semiconductor process using machine learning.

FIG. 1 is a flowchart illustrating a method of correcting a layout for semiconductor process according to example embodiments.

FIGS. 2 and 3 are block diagrams illustrating a system performing a method of correcting a layout for semiconductor process according to example embodiments.

FIGS. 4A, 4B and 4C are diagrams illustrating process proximity correction and optical proximity correction to which a method of correcting a layout for semiconductor process according to example embodiments is to be applied.

FIG. 5 is a flowchart illustrating an example of performing a first layout correction operation in FIG. 1.

FIG. 6 is a flowchart illustrating an example of performing an image-based shift correction in FIG. 5.

FIGS. 7A and 7B are diagrams illustrating operations of FIGS. 5 and 6.

FIG. 8 is a flowchart illustrating an example of performing a second layout correction operation in FIG. 1.

FIG. 9 is a flowchart illustrating an example of performing a feature-based segment correction in FIG. 8.

FIGS. 10A and 10B are diagrams illustrating operations of FIGS. 8 and 9.

FIG. 11 is a flowchart illustrating a method of correcting a layout for semiconductor process according to example embodiments.

FIG. 12 is a flowchart illustrating an example of training at least one of a first machine learning model and a second machine learning model in FIG. 11.

FIGS. 13A, 13B and 13C are diagrams illustrating a first machine learning model that is used in a method of correcting a layout for semiconductor process according to example embodiments.

FIG. 14 is a flowchart illustrating an example of training at least one of a first machine learning model and a second machine learning model in FIG. 11.

FIGS. 15A, 15B and 15C are diagrams illustrating a second machine learning model that is used in a method of correcting a layout for semiconductor process according to example embodiments.

FIGS. 16A, 16B and 16C are diagrams illustrating a method of correcting a layout for semiconductor process according to example embodiments.

FIG. 17 is a flowchart illustrating a method of manufacturing a semiconductor device according to example embodiments.

### DETAILED DESCRIPTION

Embodiments of the disclosure relate to semiconductor fabrication. In some cases, errors in the fabrication process may result in deficient or unusable semiconductor devices. The incidence of these errors depends on the design layout of the semiconductors. The design layout may include layout patterns, circuit patterns, and corresponding polygons for semiconductor processes to form process patterns of the semiconductor device during manufacturing.

In some cases, portions of the process patterns that may result in distortions can be predicted during the design phase and the layout patterns can be modified based on the expected distortions. The modified layout patterns can be reflected in the design layout.

In some cases, layout patterns can be corrected using a machine learning model. However, it is difficult to simultaneously correct various possible errors, and some machine learning models do not provide a high degree of accuracy in the predicted modifications. Accordingly, embodiments of the disclosure provide methods for correcting the layout for the semiconductor process with a high degree of accuracy using two different machine learning models.

For example, a corrected design layout may be obtained by correcting the layout pattern using two different machine learning models alternately and repetitively. Accordingly, various possible errors (e.g., shift errors, segment errors, etc.) may be efficiently corrected or compensated. In one embodiment, a first machine learning model is used to correct shift errors and a second machine learning mode is used to correct segment errors.

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

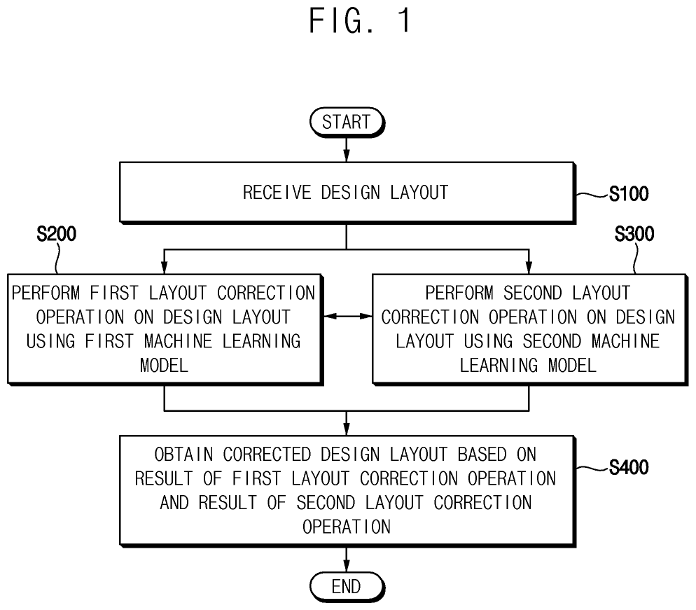

FIG. 1 is a flowchart illustrating a method of correcting a layout for semiconductor process according to example embodiments.

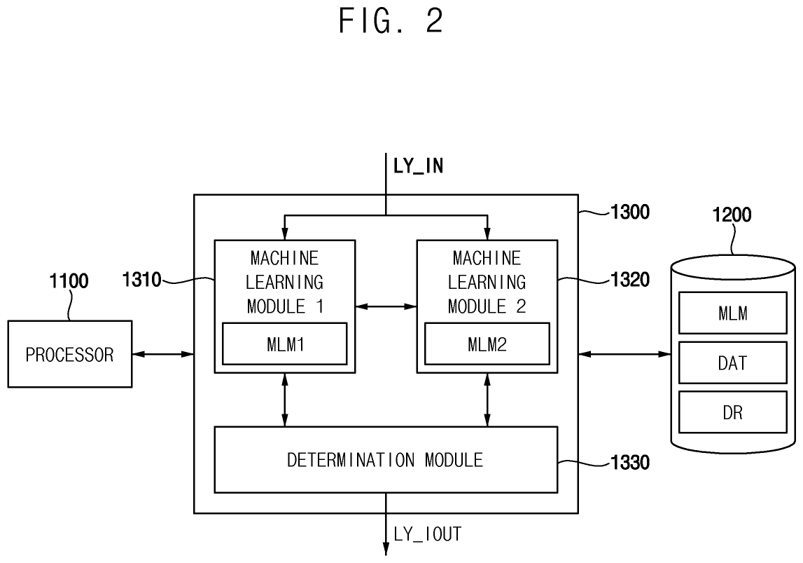

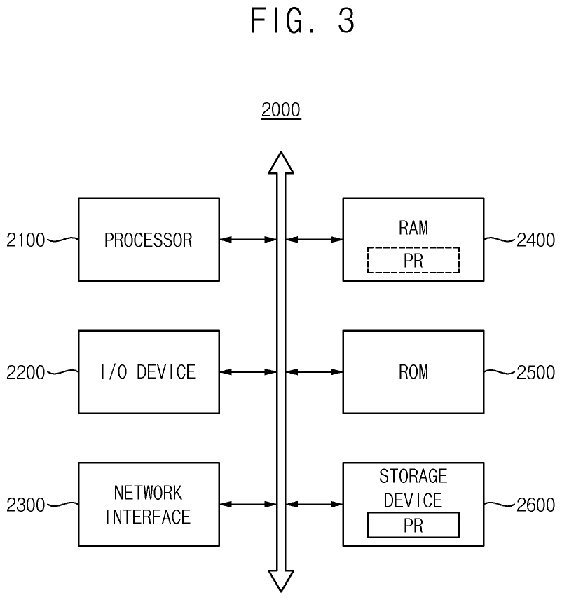

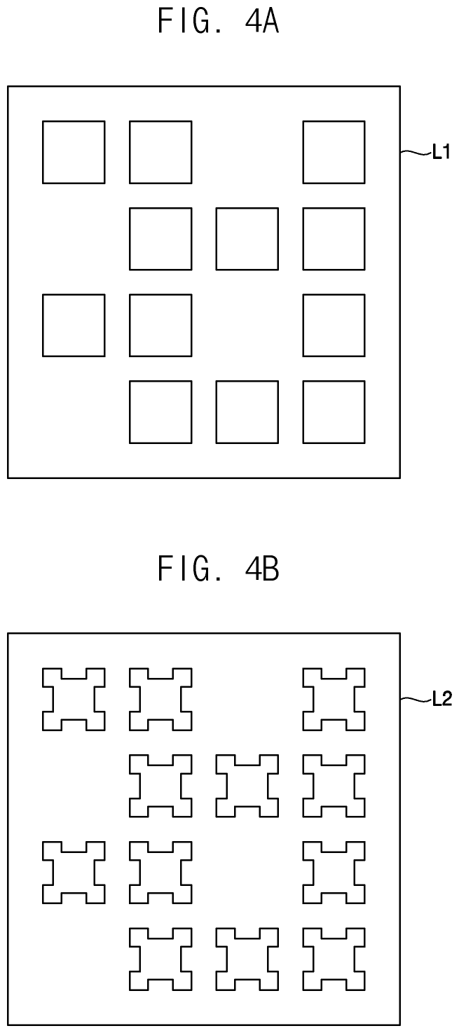

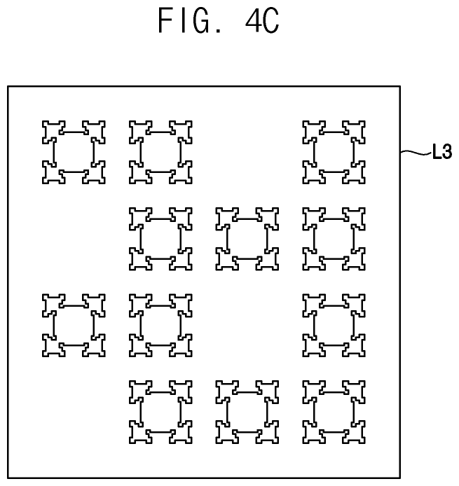

Referring to FIG. 1, a method of correcting a layout for semiconductor process according to example embodiments is illustrated. The method of correcting the layout for the semiconductor process may be performed in a semiconductor designing/manufacturing phase or during a designing/manufacturing procedure of a semiconductor device (or semiconductor integrated circuit). In some examples, the method of correcting the layout for the semiconductor process according to example embodiments may be used to perform process proximity correction (PPC). In some examples, the method of correcting the layout for the semiconductor process according to example embodiments may be used to perform an optical proximity correction (OPC). In some examples, the method may be performed by a system or a tool for layout correction or semiconductor design. For example, the system or the tool for the layout correction or the semiconductor design may be a program (or program code) that includes a plurality of instructions executable by at least one processor. The system or the tool will be described with reference to FIGS. 2 and 3, and the process proximity correction and the optical proximity correction will be described with reference to FIGS. 4A, 4B and 4C.

Example embodiments of the method for correcting the layout of a semiconductor process includes receiving a design layout that includes a layout pattern for the semiconductor process to create a process pattern of the semiconductor device (operation S100). For example, the design layout may be provided in the form of data having graphic design system (GDS) format or in the form of an image having NGR format. The NGR format is an example file format used to capture images of semiconductor layouts. However, embodiments of the present disclosure are not limited thereto, and the design layout may have various other data or image formats.

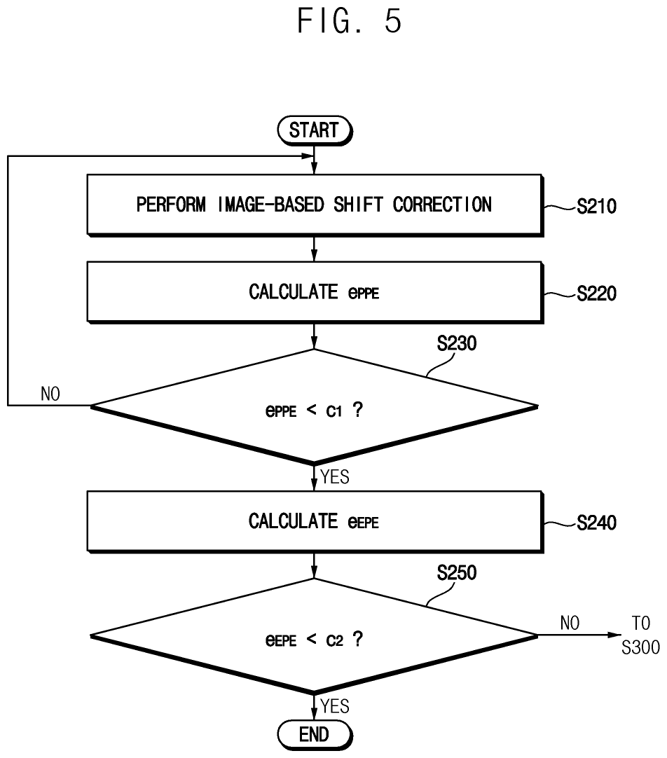

A first layout correction operation is performed on the design layout using a first machine learning model (operation S200). For example, the first machine learning model may be an image-based machine learning model, and the first layout correction operation may be performed using an image of a layout. An “image-based machine learning model” refers to a type of machine learning model that takes an image (such as a pixel-based image) as input and uses the image to make predictions or perform operations. For example, the first machine learning model used may take an image of the layout pattern as input and performs a shift correction to adjust or modify the position of the pattern. For example, the image of the layout used in the first layout correction operation may include a pixel-based image (e.g., an image including a plurality of pixel data) associated with the layout pattern. For example, a shift correction in which a position (or location or placement) of the layout pattern is adjusted or modified may be performed by the first layout correction operation. Operation S200 will be described with reference to FIG. 5 and the like.

A second layout correction operation is performed on the design layout using a second machine learning model different from the first machine learning model (operation S300). For example, the second machine learning model may be a feature-based machine learning model, and the second layout correction operation may be performed using information of a pattern.

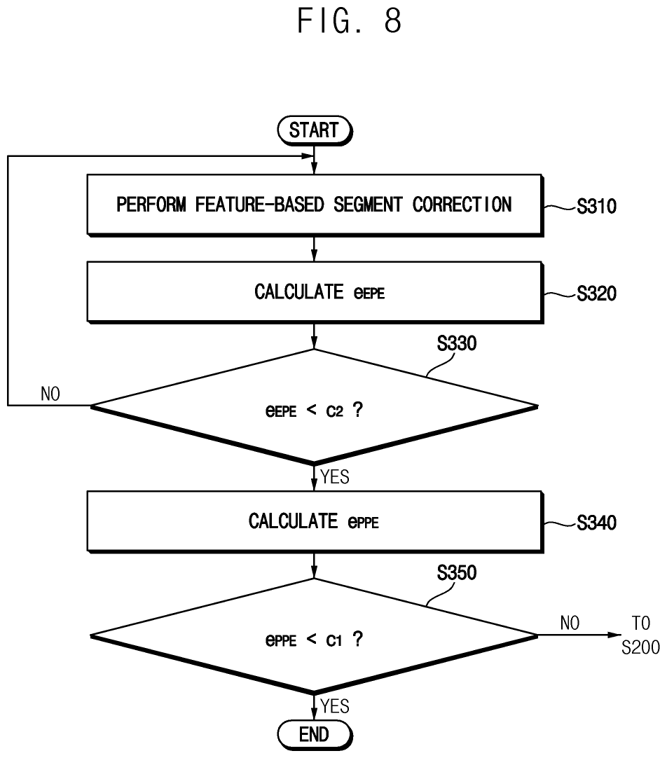

A feature-based machine learning model may be a machine learning model that uses specific features (or characteristics) of the patterns to make predictions or corrections. The features may be in a form other than an image, such as a set of edges and information associated with the edges. For example, the feature-based process proximity correction may be a type of layout correction method that uses a feature-based machine learning model to make corrections based on the proximity of the patterns. For example, the information of the pattern used in the second layout correction operation may include edge (or side) information associated with the layout pattern. For example, a segment correction in which a position (or location or placement) of a segment that is a part of an edge of the layout pattern is adjusted or modified may be performed by the second layout correction operation. Operation S300 will be described with reference to FIG. 8 and the like.

A machine learning model may be implemented using an artificial neural network (ANN). ANN is a hardware or a software component that includes a number of connected nodes (i.e., artificial neurons), which loosely correspond to the neurons in a human brain. Each connection, or edge, transmits a signal from one node to another (like the physical synapses in a brain). When a node receives a signal, it processes the signal and then transmits the processed signal to other connected nodes. In some cases, the signals between nodes comprise real numbers, and the output of each node is computed by a function of the sum of its inputs. In some examples, nodes may determine their output using other mathematical algorithms (e.g., selecting the max from the inputs as the output) or any other suitable algorithm for activating the node. Each node and edge is associated with one or more node weights that determine how the signal is processed and transmitted.

During the training process, these weights are adjusted to improve the accuracy of the result (i.e., by minimizing a loss function which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

A convolutional neural network (CNN) may be used in computer vision or image classification systems. In some cases, a CNN may enable processing of digital images with minimal pre-processing. CNN may be characterized by the use of convolutional (or cross-correlational) hidden layers. These layers apply a convolution operation to the input before signaling the result to the next layer. Each convolutional node may process data for a limited field of input (i.e., the receptive field). During a forward pass of the CNN, filters at each layer may be convolved across the input volume, computing the dot product between the filter and the input. During the training process, the filters may be modified so that they activate when they detect a particular feature within the input.

Operation S400 includes obtaining a corrected design layout (or corrected layout) that includes a corrected layout pattern corresponding to the layout pattern, based on the results of the first and second layout correction operations. For example, the corrected design layout may be obtained by combining (e.g., coupling) the result of the first layout correction operation and the result of the second layout correction operation.

In some example embodiments, the corrected design layout may be obtained by performing the first layout correction operation one or more times and the second layout correction one or more times. In some examples, the first layout correction operation and the second layout correction operation may be performed alternately and repeatedly. For example, the first layout correction operation may be performed once, followed by the second layout correction operation once, and then the first layout correction operation again. However, embodiments of the present disclosure are not limited thereto. Alternatively, the first layout correction operation may be performed multiple times, and then followed by the second layout correction operation performed multiple times, and then the first layout correction operation performed multiple times. Although example embodiments are described that the first layout correction operation is performed and then the second layout correction operation is performed, embodiments of the present disclosure are not limited to a specific order or frequency of performing the first and second layout correction operations, and may be determined based on the semiconductor process.

In some example embodiments, the layout pattern included in the design layout may correspond to a photoresist pattern, and the design layout may be corrected by performing the process proximity correction using the first machine learning model and the second machine learning model. For example, the design layout may be a target layout in after-cleaning inspection (ACI), and the corrected design layout may be a target layout of a photoresist pattern in after-development inspection (ADI).

In some example embodiments, the layout pattern included in the design layout may correspond to a pattern of a photomask, and the design layout may be corrected by performing the optical proximity correction using the first machine learning model and the second machine learning model. According to some embodiments, by using a machine learning models, optical proximity correction modifies the pattern to account for distortions, resulting in a more precise pattern transfer and better performance of the final semiconductor device. For example, the design layout may be a target layout of a photoresist pattern in the after-development inspection, and the corrected design layout may be a layout of a photomask.

The design layout may include a plurality of layout patterns, circuit patterns or corresponding polygons for semiconductor processes to form process patterns (or semiconductor patterns) of the semiconductor device when manufacturing the semiconductor device. In the semiconductor designing phase, portions of the process patterns to be distorted may be predicted, the layout patterns may be modified based on the predicted distortions in advance to the real semiconductor processes (or physical processes), and the modified layout patterns may be reflected in the design layout. Conventionally, the layout patterns were corrected using only one machine learning model, making it difficult to simultaneously correct various possible errors, causing relatively low correction accuracy.

According to example embodiments, the corrected design layout may be obtained using two different machine learning models. For example, the corrected design layout may be obtained by correcting the layout pattern using two different machine learning models alternately and repetitively. Accordingly, various possible errors (e.g., shift errors, segment errors, edge placement error, etc.) may be efficiently corrected or compensated substantially simultaneously or concurrently, and the accuracy of correction may be increased. Segment error (or targeting error) refers to the deviation of a pattern segment from its intended location on the semiconductor substrate. The segment error may lead to a misalignment between different pattern layers. Edge placement error refers to the deviation of the position of a pattern edge from its intended or desired position in a semiconductor layout pattern. According to some embodiments, a first machine learning model including a convolutional neural network (CNN) may be used to predict the segment error, and a second machine learning model including a linear regression model may be used to predict the edge placement error.

FIGS. 2 and 3 are block diagrams illustrating a system performing a method of correcting a layout for semiconductor process according to example embodiments.

Referring to FIG. 2, a system 1000 includes a processor 1100, a storage device 1200 and a layout correction module 1300.

According to some embodiments, the term “module” may refer to, but is not limited to, a software, hardware component, or firmware, such as a field programmable gate array (FPGA) or an application specific integrated circuit (ASIC), which performs certain tasks. A module may be configured to reside in a tangible addressable storage medium and be configured to execute on one or more processors. For example, a “module” may include components such as software components, object-oriented software components, class components and task components, and processes, functions, Routines, segments of program code, drivers, firmware, microcode, circuitry, data, databases, data structures, tables, arrays, and variables. A “module” may be divided into a plurality of “modules” that perform detailed functions.

In some example embodiments, the system 1000 may be a computing system. In some example embodiments, the system 1000 may be a dedicated system for the method of correcting the layout for the semiconductor process according to example embodiments, and may be referred to as a layout correction system. In some example embodiments, the system 1000 may be a dedicated system for a method of designing a semiconductor device using the method of correcting the layout for the semiconductor process according to example embodiments, and may be referred to as a semiconductor design system. For example, the system 1000 may include various design programs, verification programs, or simulation programs.

The processor 1100 may control an operation of the system 1000, and may be utilized when the layout correction module 1300 performs computations. For example, the processor 1100 may include a micro-processor, an application processor (AP), a central processing unit (CPU), a digital signal processor (DSP), a graphic processing unit (GPU), a neural processing unit (NPU), or the like. Although FIG. 2 illustrates that the system 1000 includes the processor 1100, embodiments of the present disclosure are not limited thereto. For example, the system 1000 may include a plurality of processors. In addition, the processor 1100 may include cache memories to increase computation capacity.

The storage device 1200 may store data used for the operation of the system 1000 and the layout correction module 1300. The store device 1200 may store data executable by the processor 1100. For example, the storage device 1200 may store machine learning models (or machine learning model related data) MLM, a plurality of data DAT, and design rules (or design rule related data) DR. For example, the plurality of data DAT may include sample data, simulation data, real data, and various other data. The real data may also be referred to herein as actual data or measured data from the manufactured semiconductor device or manufacturing process. The machine learning models MLM and the design rules DR may be provided to the layout correction module 1300 from the storage device 1200.

In some example embodiments, the storage device 1200 may include any non-transitory computer-readable storage medium used to provide commands or data to a computer. For example, the non-transitory computer-readable storage medium may include a volatile memory such as a static random access memory (SRAM), a dynamic random access memory (DRAM), or the like, and a nonvolatile memory such as a flash memory, a magnetic random access memory (MRAM), a phase-change random access memory (PRAM), a resistive random access memory (RRAM), or the like. The non-transitory computer-readable storage medium may be inserted into the computer, integrated in the computer, or coupled to the computer through a communication medium such as a network or a wireless link.

The layout correction module 1300 may generate an output layout LY_OUT by correcting or compensating an input layout LY_IN. The layout correction module 1300 may correct the layout for the semiconductor process according to example embodiments described with reference to FIG. 1.

The layout correction module 1300 may include a first machine learning module 1310, a second machine learning module 1320, and a determination module 1330.

According to some embodiments, the first machine learning module 1310 and the second machine learning module 1320 receive the input layout LY_IN. In some examples, the input layout LY_IN may correspond to the design layout including the layout pattern for the semiconductor process to form a process pattern of the semiconductor device in FIG. 1. The first machine learning module 1310 executes a first machine learning model MLM1, and performs a first layout correction operation on the input layout LY_IN using the first machine learning model MLM1. The second machine learning module 1320 executes a second machine learning model MLM2, and performs a second layout correction on the input layout LY_IN operation using the second machine learning model MLM2. In some examples, the first machine learning module 1310 may perform operations S100 and S200 in FIG. 1, and the second machine learning module 1320 may perform operations S100 and S300 in FIG. 1.

The determination module 1330 may obtain and provide the output layout LY_OUT based on a result of the first layout correction operation and a result of the second layout correction operation. The output layout LY_OUT may correspond to the corrected design layout including the corrected layout pattern corresponding to the layout pattern in FIG. 1. In some examples, the determination module 1330 may perform operation S400 in FIG. 1.

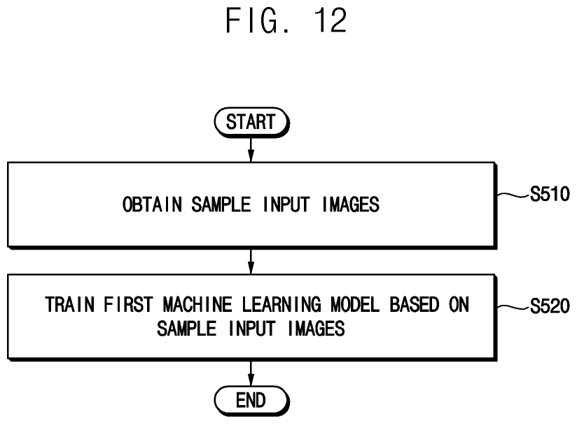

In some example embodiments, the layout correction module 1300 may correct a layout for semiconductor process according to example embodiments, which will be described with reference to FIG. 11. For example, the first machine learning module 1310 and the second machine learning module 1320 may train the first machine learning model MLM1 and the second machine learning model MLM2, respectively.

In some example embodiments, the layout correction module 1300 may be implemented as executable instructions or program code that may be executed by the processor 1100. For example, the first machine learning module 1310, the second machine learning module 1320 and the determination module 1330 that are included in the layout correction module 1300 may be stored in computer readable medium. For example, the processor 1100 may load the instructions or program code to a working memory (e.g., a DRAM, etc.). In some examples, the processor 1100 may load the instructions or program code to a non-transitory memory.

In some example embodiments, the processor 1100 may efficiently execute instructions or program code included in the layout correction module 1300. For example, the processor 1100 may efficiently execute the instructions or program code of the first machine learning module 1310, the second machine learning module 1320 and the determination module 1330 that are included in the layout correction module 1300. For example, the processor 1100 may receive information corresponding to the first machine learning module 1310, the second machine learning module 1320 and the determination module 1330 to operate the first machine learning module 1310, the second machine learning module 1320 and the determination module 1330. For example, the processor 1100 may receive input data, parameters, or hyper-parameters for operating the first machine learning module 1310, the second machine learning module 1320, and the determination module 1330.

In some example embodiments, the first machine learning module 1310, the second machine learning module 1320, and the determination module 1330 may be implemented as a single integrated module. In some example embodiments, the first machine learning module 1310, the second machine learning module 1320, and the determination module 1330 may be implemented as separate and different modules.

Referring to FIG. 3, a system 2000 includes a processor 2100, an input/output (I/O) device 2200, a network interface 2300, a random access memory (RAM) 2400, a read only memory (ROM) 2500 or a storage device 2600. FIG. 3 illustrates an example where components of the layout correction module 1300 in FIG. 2 are implemented in software.

The system 2000 may be a computing system, including a fixed computing system and a portable computing system. For example, the computing system may be a fixed computing system such as a desktop computer, a workstation or a server, or may be a portable computing system such as a laptop computer.

The processor 2100 may be substantially the same as the processor 1100 in FIG. 2. For example, the processor 2100 may include a core or a processor core for executing an arbitrary instruction set (for example, intel architecture-32 (IA-32), 64 bit extension IA-32, x86-64, PowerPC, Sparc, MIPS, ARM, IA-64, etc.). A processor core refers to a processing unit within a CPU that can execute instructions independently of other processing units within the CPU. In some examples, a CPU may contain multiple processor cores, which allows the CPU to perform multiple tasks simultaneously and increase the CPU's processing power. For example, the processor 2100 may access a memory (e.g., the RAM 2400 or the ROM 2500) through a bus, and may execute instructions stored in the RAM 2400 or the ROM 2500. As illustrated in FIG. 3, the RAM 2400 may store a program PR corresponding to the layout correction module 1300 in FIG. 2 or at least some elements of the program PR, and the program PR may allow the processor 2100 to perform operations for the layout correction in the semiconductor designing phase (e.g., operations S100, S200, S300 and S400 in FIG. 1).

In some examples, the program PR may include a plurality of instructions or procedures executable by the processor 2100, and the plurality of instructions or procedures included in the program PR may allow the processor 2100 to perform the operations for the layout correction in the semiconductor designing phase according to example embodiments. In some examples, an individual procedure may denote a series of instructions for performing a task. A procedure may be referred to as a function, a routine, a subroutine, or a subprogram. An individual procedure may process data provided from the outside or data generated by another procedure.

In some example embodiments, the RAM 2400 may include any volatile memory such as an SRAM, a DRAM, or the like.

The storage device 2600 may store the program PR. The program PR may be loaded from the storage device 2600 to the RAM 2400 before being executed by the processor 2100. In some examples, at least portions of the program PR may be loaded before being executed by the processor 2100. The storage device 2600 may store a file written in a program language, and the program PR generated by a compiler or the like or at least some elements of the program PR may be loaded to the RAM 2400.

The storage device 2600 may store data to be processed by the processor 2100, or data obtained by the processor 2100 during the processing process. The processor 2100 may process the data stored in the storage device 2600 to generate new data, based on the program PR and may store the generated data in the storage device 2600.

The I/O device 2200 may include an input device, such as a keyboard, a pointing device, or the like, and may include an output device such as a display device, a printer, or the like. For example, an input device may be a computer mouse, keyboards, keypads, trackballs, and voice recognition devices. An input component may include any combination of devices that allow users to input information into a computing device, such as buttons, a keyboard, switches, and/or dials. In addition, the input component may include a touch-screen digitizer overlaid onto the display that can sense touch and interact with the display. For example, a user may trigger, through the I/O devices 2200, execution of the program PR by the processor 2100, and may provide or check various inputs, outputs or data, etc.

The network interface 2300 may provide access to a network external to the system 2000. For example, the network may include a plurality of computing systems and communication links, and the communication links may include wired links, optical links, wireless links, or arbitrary other type links. The system 2000 may receive various inputs through the network interface 2300, and may transmit various outputs to another computing system through the network interface 2300. In some example embodiments, the computer program code or the layout correction module 1300 may be stored in a transitory or non-transitory computer readable medium. In some example embodiments, values resulting from the layout correction performed by the processor or values obtained from arithmetic processing performed by the processor may be stored in a transitory or non-transitory computer readable medium. A non-transitory computer-readable medium refers to any form of storage medium that is not a transitory signal. A non-transitory computer-readable medium may store data or program code in a tangible or permanent form, such as a hard drive, flash drive, CD-ROM, DVD, or any other physical medium that can be used to store digital information. In some example embodiments, intermediate values during the layout correction or various data generated by the layout correction may be stored in a transitory or non-transitory computer readable medium. However, embodiments of the present disclosure are not limited thereto.

FIGS. 4A, 4B and 4C are diagrams illustrating process proximity correction and optical proximity correction to which a method of correcting a layout for semiconductor process according to example embodiments is to be applied.

Referring to FIGS. 2, 4A, 4B and 4C, the layout correction module 1300 may receive a first layout L1 as the input layout LY_IN. For example, the first layout L1 may be a target layout in the after-cleaning inspection.

The layout correction module 1300 may generate a second layout L2 by performing the process proximity correction on the first layout. For example, the process proximity correction may be performed by inference based on machine learning. For example, the second layout L2 may be a target layout of a photoresist pattern in the after-development inspection.

The process proximity correction may compensate for distortion of the semiconductor patterns caused by factors such as etching skew or the characteristics of the patterns during the etching process. For example, the process proximity correction may predict portions of the patterns to be distorted and modify the predicted distortions in advance to compensate for the distortion arising from physical semiconductor processes such as the etching process. As used herein, “physical processes” may refer to processes that are performed by mechanical equipment, rather than by hardware such as the system 1000 or software such as the layout correction module 1300. For example, the physical processes may be physical manufacturing processes that are carried out by machines and equipment, such as etching, deposition, and lithography. For example, the physical processes may include physical changes to the materials being used and are not directly related to the operation of hardware or software systems like the layout correction module 1300 or the system 1000.

The layout correction module 1300 may generate a third layout L3 by performing the optical proximity correction on the second layout L2. For example, the optical proximity correction may be performed by inference based on machine learning. For example, the optical proximity correction may be performed using knowledge and patterns learned by the machine learning models to make predictions or corrections for new data. For example, the machine learning models may have been trained on a set of data containing known patterns and the corresponding corrections needed, and then used to make predictions for new patterns that require correction. For example, the third layout L3 may be a layout of a photomask.

The optical proximity correction may compensate for distortion of the photoresist patterns by effects from etching skew or effects of characteristics of the patterns while the photoresist patterns are formed. For example, the optical proximity correction may predict portions of the patterns to be distorted and modify the predicted distortions in advance to compensate for the distortion arising from physical semiconductor processes such as the etching process.

The semiconductor devices may be manufactured based on the third layout L3. For example, the photoresist patterns may be formed on an object (e.g., a semiconductor substrate) using the photomask of the third layout L3. By performing the etching process, portions of the object that are not covered by the photoresist patterns may be removed. After the optical lithography process, the remaining photoresist patterns may be removed, and the semiconductor fabrication processes can then be completed.

FIG. 4A illustrates an example of the first layout L1. For example, the first layout L1 may include rectangular patterns in which vias may be formed. Vias may be small holes in a semiconductor material or circuit board that are used to connect different layers or components of the material or board. Vias allow electrical signals or power to pass through from one layer to another. For example, the rectangular patterns in the first layout may contain multiple vias. The first layout L1 may specify a target layout in the after-cleaning inspection. For example, the first layout L1 may be a layout including process patterns formed by the semiconductor processes.

FIG. 4B illustrates an example of the second layout L2. The second layout L2 of FIG. 4B may include patterns that are modified based on the patterns of the first layout L1 of FIG. 4A. The second layout L2 may specify a target layout in the after-development inspection. For example, the second layout L2 may be a layout including photoresist patterns.

Although FIGS. 4A and 4B illustrate that the patterns are modified around a similar shape, embodiments of the present disclosure are not limited thereto, and the patterns may be modified to different shapes according to example embodiments.

FIG. 4C illustrates an example of the third layout L3. The third layout L3 of FIG. 4C may include patterns that are modified based on the patterns of the second layout L2 of FIG. 4B. The third layout L3 may specify a layout of a photomask.

Although FIGS. 4B and 4C illustrate that the patterns are modified around a similar shape convenience of illustration, embodiments of the present disclosure are not limited thereto, and the patterns may be modified to form different shapes according to example embodiments.

The procedure to generate the second layout L2 of FIG. 4B from the first layout L1 of FIG. 4A may be based on the process proximity correction. For example, the process proximity correction may be performed using machine learning model and may be performed based on images and features, respectively. In some example embodiments, both image-based and feature-based process proximity correction may be performed. The image-based process proximity correction comprises using images of the layout, which are processed to predict a critical dimension (CD). The processed images are then corrected based on the predicted CD. Critical dimension (CD) refers to the size of a feature in a semiconductor device, such as a transistor gate, that needs to be precisely controlled during the manufacturing process.

According to some embodiments, the feature-based process proximity correction is based on the edge information of the patterns, such as their widths and spaces. The image-based process proximity correction may be performed using the image-based machine learning model. When the images are modeled during the image-based process proximity correction, the grid dependency may occur while dividing the pixel size, and thus there may be a problem in an increase of an edge placement error (EPE). Edge placement error (EPE) refers to the deviation of the location of a patterned feature from its intended location. For example, EPE may be used to measure the distance between the center of a feature and its intended position.

The feature-based process proximity correction may be performed using the feature-based machine learning model. When specific values of patterns are modeled during the feature-based process proximity correction, it may be difficult to consider a space in a diagonal direction, and thus there may be a problem in an increase of a pattern placement error (PPE). Pattern placement error (PPE) may be the deviation between the target position of a pattern and its actual position after the lithography process. For example, PPE may measure the difference between the intended layout of a pattern and the actual placement of that pattern on the semiconductor device.

In the method of correcting the layout for the semiconductor process according to example embodiments, the training and inference of the machine learning module may be performed based on both images and features of the layout patterns. Accordingly, the process proximity correction may be performed with the increased accuracy and reduced amount of computations.

However, although the procedure to generate the second layout L2 from the first layout L1 may be based on the process proximity correction, example embodiments are not limited to this method. For example, the procedure to generate the third layout L3 of FIG. 4C from the second layout L2 of FIG. 4B may be based on the optical proximity correction. For example, the optical proximity correction may be performed using machine learning model and may be performed based on images and features (e.g., both the image-based optical proximity correction and the feature-based optical proximity correction may be performed).

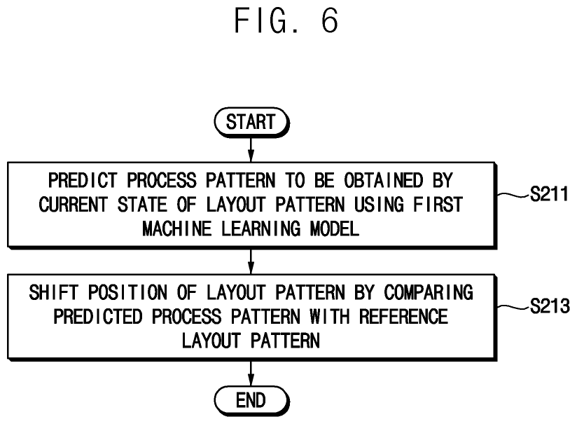

FIG. 5 is a flowchart illustrating an example of performing a first layout correction operation in FIG. 1. FIG. 6 is a flowchart illustrating an example of performing an image-based shift correction in FIG. 5. A shift correction mentioned may be an image-based process proximity correction that focuses on correcting the shifts or displacements of the patterns in the layout.

Referring to FIGS. 1, 5 and 6, when performing the first layout correction operation on the design layout using the first machine learning model (operation S200), the first machine learning model may be the image-based machine learning model, and the first layout correction operation may be performed using the pixel-based image associated with the layout pattern. For example, the pixel-based image is connected to or related to the layout pattern. For example, the pixel-based image is used to represent the layout pattern in some form and is used as input for the image-based machine learning model to perform the layout correction operation.

In operation S200, an image-based shift correction of adjusting or modifying a position of the layout pattern may be performed (operation S210). For example, when the shift correction is performed, only the overall position of the layout pattern (e.g., a centroid (or center) of the layout pattern) may be moved or shifted as a whole, and a shape of the layout pattern (e.g., positions or arrangement of edges of the layout pattern) may be maintained without modification. For example, when the shift correction is applied, the position of the entire layout pattern is moved or shifted while the shape of the pattern remains unchanged.

For example, in operation S210, the first machine learning model may predict the process pattern that is to be obtained by the current state of the layout pattern (operation S211). For example, a contour of the process pattern may be predicted. For example, a first predicted process pattern may be obtained by performing operation S211.

In some example embodiments, Operation S213 shifts the position of the layout pattern by comparing a predicted process pattern (e.g., the first predicted process pattern obtained in operation S211) with a reference layout pattern. For example, a centroid of the predicted process pattern may be compared with a centroid of the reference layout pattern, and the position of the layout pattern may be shifted such that the centroid of the predicted process pattern and the centroid of the reference layout pattern coincide as close as possible.

In some example embodiments, when the design layout is corrected by performing the process proximity correction using the first and second machine learning models, the reference layout pattern may be a layout pattern included in an ACI target, e.g., the target layout in the after-cleaning inspection. The design layout and the layout pattern included in the design layout may be an ADI target, e.g., the target layout of the photoresist in the after-development inspection, and a layout pattern included in the ADI target.

Thereafter, a result of performing the image-based shift correction in operation S210 may be verified.

For example, after operation S210 is performed, a first error value ePPE associated with the shifted layout pattern may be calculated (operation S220). This error value measures the discrepancy between the predicted process pattern of the shifted layout pattern and the reference layout pattern. For example, the process pattern that is to be obtained by the shifted layout pattern may be re-predicted using the first machine learning model, and the first error value e_{PPE} may be calculated by comparing a re-predicted process pattern with the reference layout pattern. For example, it may be determined whether a predetermined first criterion is satisfied by comparing the first error value e_{PPE} with the first reference value c₁.

In some example embodiments, the first error value e_{PPE} may be a pattern placement error value that represents a difference between the centroid of the predicted process pattern and the centroid of the reference layout pattern. A centroid may be the center point of a geometric shape. In cases of two-dimensional shapes, the centroid may the point at which the shape would balance if it were cut out of a flat sheet of uniform thickness. For example, in a rectangle, the centroid is located at the intersection of the diagonals. For example, the first error value e_{PPE} may be calculated by comparing a position of the centroid of the predicted process pattern and a position of the centroid of the reference layout pattern.

When the first error value e_{PPE} is greater than or equal to the first reference value c₁ (operation S230: NO), operation S210 may be re-performed, and thus the position of the layout pattern may be re-shifted. In some examples, operation S210 may be repeatedly performed until the first criterion is satisfied.

When the first error value e_{PPE} is smaller than the first reference value c₁ (operation S230: YES), the position of the layout pattern may be maintained without performing operation S210 again.

In addition, when the first error value e_{PPE} is smaller than the first reference value c₁ (operation S230: YES), a second error value e_{EPE} associated with or related to the shifted layout pattern may be calculated (operation S240), and the second error value e_{EPE} may be compared with a second reference value c₂ (operation S250). For example, similarly to operations S220 and S230, the process pattern that is to be obtained by the shifted layout pattern may be re-predicted using the first machine learning model, and the second error value e_{EPE} may be calculated by comparing a re-predicted process pattern with the reference layout pattern. For example, a second criterion different from the first criterion may be determined by comparing the second error value eEPE with a second reference value c₂. If the second error value eEPE is greater than or equal to the second reference value c₂, the second criterion is not satisfied (operation S330: NO).

In some example embodiments, the second error value e_{EPE} may be an edge placement error value that represents a difference between an edge (or contour) of the predicted process pattern and an edge of the reference layout pattern. For example, “edge” may refer to the boundary of a pattern, and “contour” may refer to the complete outline or shape of the pattern. For example, the second error value e_{EPE} may be calculated by comparing a position of the edge of the predicted process pattern with a position of the edge of the reference layout pattern.

When the second error value e_{EPE} is greater than or equal to the second reference value c₂ (operation S250: NO), operation S300 may be performed. In some examples, when the first criterion is satisfied but the second criterion is not satisfied, the layout correction according to example embodiments may be continuously performed.

When the second error value e_{EPE} is smaller than the second reference value c₂ (operation S250: YES), the first layout correction operation may be terminated. In some examples, when both the first and second criteria are satisfied, the layout correction may be successfully completed and may be terminated according to example embodiments of the present disclosure.

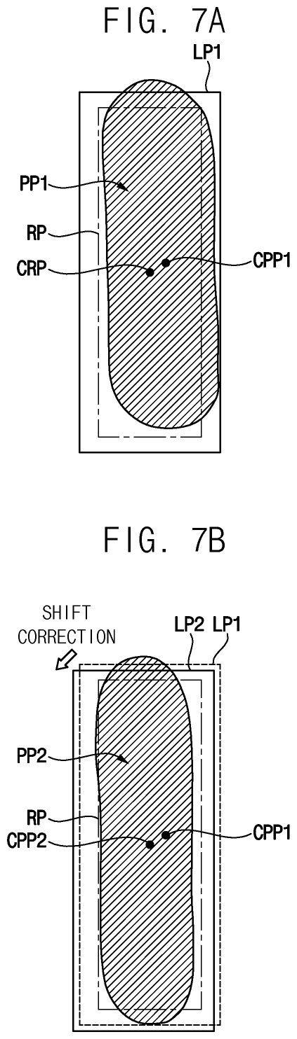

FIGS. 7A and 7B are diagrams illustrating operations of FIGS. 5 and 6.

Referring to FIG. 7A, an example of a layout pattern LP1 before operation S210 is performed is illustrated. For example, the layout pattern LP1 may represent an initial layout pattern in which no layout correction operation is performed. For example, the layout pattern LP1 may represent a layout pattern in which edges are increased by a predetermined size in each direction, as compared with a reference layout pattern RP. However, embodiments of the present disclosure may not be limited thereto. For example, individual edges may be increased by different sizes.

A process pattern PP1 may represent a predicted process pattern obtained by applying the first machine learning model to the layout pattern LP1. When a centroid CPP1 of the process pattern PP1 and a centroid CRP of the reference layout pattern RP are compared with each other, a shift error is relatively large because the process pattern PP1 is biased to the right with respect to the reference layout pattern RP. In addition, a segment error is also relatively large because a position of an upper portion of a contour of the process pattern PP1 and a position of an upper edge of the reference layout pattern RP are different from each other.

Referring to FIG. 7B, an example of a layout pattern LP2 obtained by performing operation S210 on the layout pattern LP1 of FIG. 7A is illustrated. In FIG. 7B, the layout pattern LP1 before the shift correction is illustrated as dotted lines, and the layout pattern LP2 obtained by performing the shift correction is illustrated as solid lines. As the shift correction is performed, the layout pattern LP2 may be moved leftward and downward with respect to the layout pattern LP1. The reference layout pattern RP may be fixed without performing the shift correction.

A process pattern PP2 may represent a process pattern that is predicted to be obtained by the layout pattern LP2 using the first machine learning model. The shift error is reduced because a centroid CPP2 of the process pattern PP2 is moved leftward, as compared with the centroid CPP1 of the process pattern PP1 of FIG. 7A. However, the segment error is still large because a position of an upper portion of a contour of the process pattern PP2 and the position of the upper edge of the reference layout pattern RP are still different from each other and because a position of a lower portion of the contour of the process pattern PP2 and a position of a lower edge of the reference layout pattern RP become different from each other. Therefore, operation S300 may need to be performed on the layout pattern LP2.

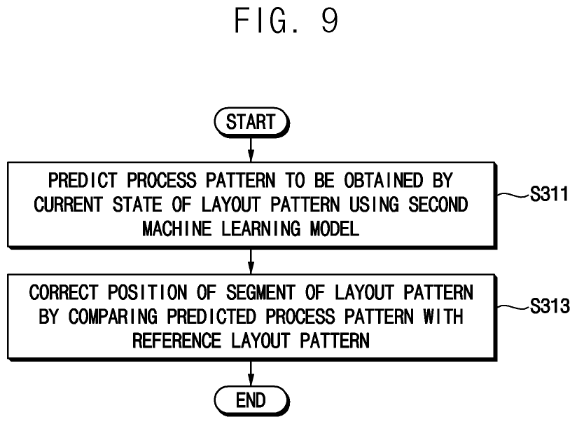

FIG. 8 is a flowchart illustrating an example of performing a second layout correction operation in FIG. 1. FIG. 9 is a flowchart illustrating an example of performing a feature-based segment correction in FIG. 8.

Referring to FIGS. 1, 8 and 9, when performing the second layout correction operation on the design layout using the second machine learning model (operation S300), the second machine learning model may be the feature-based machine learning model, and the second layout correction operation may be performed using the edge information associated with the layout pattern. The edge information may include various features of the edges of the layout pattern, such as width, position, and spacing. In some examples, edge information is used to perform the feature-based layout correction operation using the second machine learning model.

In operation S300, a feature-based segment correction of adjusting or modifying a position of a segment that is a part of an edge of the layout pattern may be performed (operation S310). For example, when the segment correction is performed, the shape of the layout pattern may be changed while the overall position of the layout pattern may be maintained. For example, the shape of the layout pattern may be changed by moving or shifting a position of at least one segment included in the layout pattern, and the overall position of the layout pattern may be maintained without moving or shifting.

For example, in operation S310, the process pattern that is to be obtained by the current state of the layout pattern may be predicted using the second machine learning model (operation S311). Operation S311 may be similar to operation S211 in FIG. 6. For example, a second predicted process pattern may be obtained by performing operation S311.

According to some embodiments, to correct the position of a segment that is part of the edge of the layout pattern, a comparison may be made between the predicted process pattern (e.g., the second predicted process pattern obtained in operation S311) and the reference layout pattern (operation S313). For example, a contour of the predicted process pattern may be compared with edges of the reference layout pattern, and the position of the segment of the layout pattern may be modified or adjusted such that the contour of the predicted process pattern and the edges of the reference layout pattern coincide as close as possible.

Thereafter, a result of performing the feature-based segment correction in operation S310 may be verified. For example, the accuracy or correctness of the segment correction may be checked by comparing the corrected layout pattern with the reference layout pattern. However, embodiments of the present disclosure are not limited thereto.

For example, after operation S310 is performed, the second error value e_{EPE} associated with the layout pattern in which the position of the segment is corrected may be re-calculated or calculated again (operation S320), and the second error value e_{EPE} may be compared with the second reference value c₂ (operation S330). Operations S320 and S330 may be similar to operations S240 and S250 in FIG. 5, respectively. For example, the process pattern that is to be obtained by the layout pattern in which the position of the segment is corrected may be re-predicted using the second machine learning model, and the second error value e_{EPE} may be re-calculated by comparing a re-predicted process pattern with the reference layout pattern. For example, whether the second criterion is satisfied may be determined by comparing the second error value e_{EPE} and the second reference value c₂.

When the second error value e_{EPE} is greater than or equal to the second reference value c₂ (operation S330: NO), operation S310 may be re-performed, and thus the position of the segment of the layout pattern may be re-corrected. In some examples, operation S310 may be repeatedly performed until the second criterion is satisfied.

According to some embodiments, the position of the segment of the layout pattern may be maintained without performing operation S310 again based on a determination that the second error value eE_{PE} is smaller than the second reference value c₂ (operation S330: YES).

In addition, when the second error value e_{EPE} is smaller than the second reference value c₂ (operation S330: YES), the first error value e_{PPE} associated with the layout pattern in which the position of the segment is corrected may be re-calculated (operation S340), and the first error value e_{EPE} may be compared with the first reference value c₁ (operation S350). Operations S340 and S350 may be similar to operations S220 and S230 in FIG. 5, respectively. For example, the process pattern that is to be obtained by the layout pattern in which the position of the segment is corrected may be re-predicted using the second machine learning model, and the first error value e_{PPE} may be re-calculated by comparing a re-predicted process pattern with the reference layout pattern. For example, whether the first criterion is satisfied may be determined by comparing the first error value e_{PPE} with the first reference value c₁.

When the first error value e_{PPE} is greater than or equal to the first reference value c₁ (operation S350: NO), operation S200 may be repeated. In some examples, when the second criterion is satisfied but the first criterion is not satisfied, the layout correction according to example embodiments may be performed continuously.

When the first error value e_{PPE} is smaller than the first reference value c₁ (operation S350: YES), the second layout correction operation may be terminated. In some examples, when both the first and second criteria are satisfied, the layout correction according to example embodiments may be successfully completed and may be terminated.

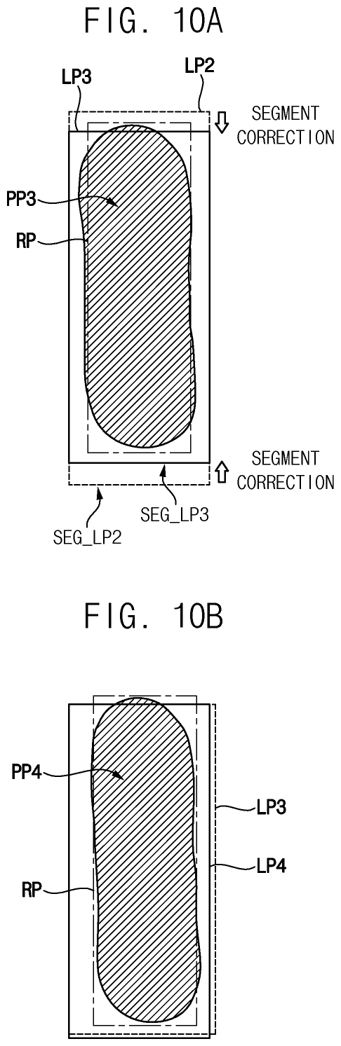

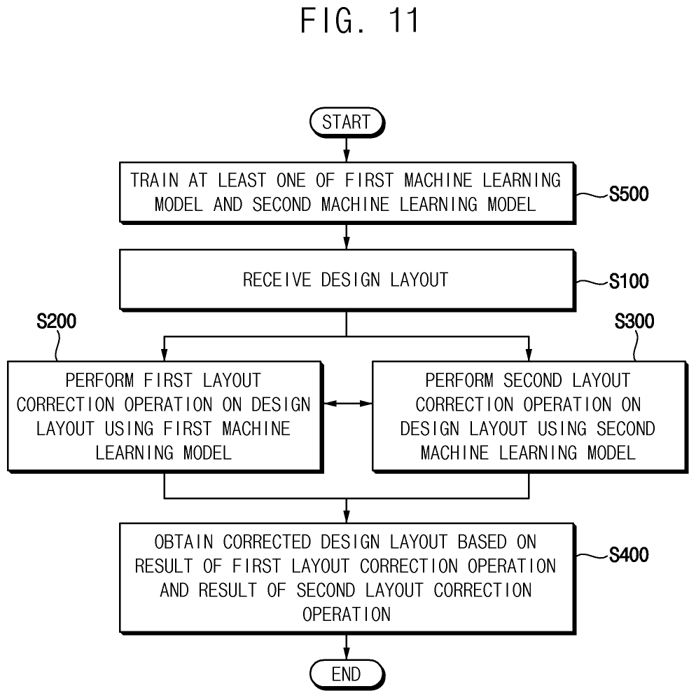

FIGS. 10A and 10B are diagrams illustrating operations of FIGS. 8 and 9. The descriptions repeated with FIGS. 7A and 7B will be omitted for brevity.

Referring to FIG. 10A, the illustrated layout pattern LP3 is an example of a pattern obtained after performing operation S310 on the layout pattern LP2 shown in FIG. 7B. During the segment correction process, a segment SEG_LP3 corresponding to a lower edge of the layout pattern LP3 may be moved upward with respect to a segment SEG_LP2 of the layout pattern LP2. In some examples, a segment corresponding to an upper edge of the layout pattern LP3 may be moved downward with respect to a segment of the layout pattern LP2.

A process pattern PP3 may represent a process pattern that is predicted to be obtained by the layout pattern LP3 using the second machine learning model. In some examples, the segment error is reduced because a contour of the process pattern PP3 is corrected to more coincide the reference layout pattern RP, as compared with the contour of the process pattern PP2 of FIG. 7B. However, some shift errors or segment errors may still exist, and thus operations S200 or S300 may need to be further performed on the layout pattern LP3.

FIG. 10B illustrates an example of a layout pattern LP4 that is obtained by alternating and repeating operations S200 and S300 according to the described embodiments. The layout pattern LP4 may correspond to the corrected layout pattern obtained in operation S400.

A process pattern PP4 may represent a process pattern that is predicted to be obtained by the layout pattern LP4, where both the shift errors and the segment error are reduced.

In the method of correcting the layout for the semiconductor process according to example embodiments, the first layout correction operation and the second layout correction operation may be performed alternately and repeatedly until a target outcome is achieved. For example, the two layout correction operations are performed in a cycle, with each operation being performed one after the other repeatedly until the first error value e_{PPE} becomes smaller than the first reference value c₁ and the second error value e_{EPE} becomes smaller than the second reference value c₂. In some examples, the shift correction and the segment correction may be alternately and repeatedly performed such that both the pattern placement error and the edge placement error are concurrently reduced and converge at the same time. In some examples, when the layout correction is performed iteratively and both the pattern placement error and the edge placement error satisfy predetermined criteria, the layout correction may be determined to be successfully completed and the layout correction may be terminated.

FIG. 11 is a flowchart illustrating a method of correcting a layout for semiconductor process according to example embodiments.

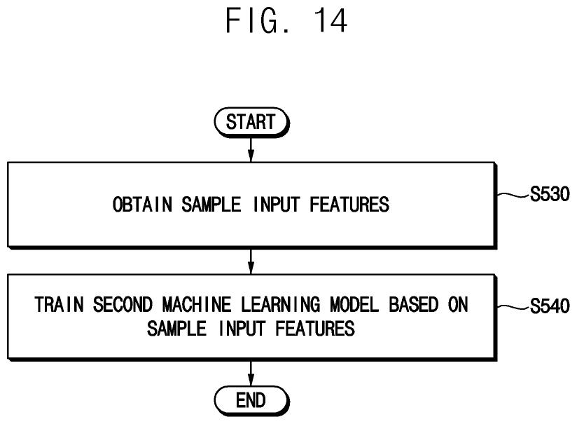

Referring to FIG. 11, in a method of correcting a layout for semiconductor process according to example embodiments, at least one of the first machine learning model and the second machine learning model may be trained (operation S500). For example, at least one of the first and second machine learning models may be trained using sample data (or training data). In some examples, the training data may be generated from a known layout pattern and its corresponding process pattern, and may be used to teach the model how to predict the process pattern for a given layout pattern. In some examples, the training data may include a variety of layout patterns and their corresponding process patterns, representing different features and complexities that the model needs to learn to accurately predict the process pattern for new, unseen layout patterns. Operation S500 will be described with reference to FIGS. 12 and 14.

Operation sS100, S200, S300 and S400 performed thereafter may be substantially the same as those described with reference to FIG. 1.

FIG. 12 is a flowchart illustrating an example of training at least one of a first machine learning model and a second machine learning model in FIG. 11.

Referring to FIGS. 11 and 12, during the training process of at least one of the first machine learning model and the second machine learning model (operation S500), sample input images may be obtained (operation S510), and the first machine learning model may be trained based on the sample input images (operation S520).

For example, forward propagation and backpropagation may be performed on the first machine learning model. For example, the training may comprise two distinct procedures: forward propagation and backpropagation. Forward propagation involves passing input data through the machine learning model to calculate the output, while backpropagation involves calculating the loss by comparing the output with ground truth labels, computing the gradient for the weights to minimize the loss, and updating the weights accordingly. The backpropagation may be referred to as an error backpropagation.

For example, during the training of the first machine learning model, the sample input images and corresponding sample reference images may be obtained, and the corresponding sample reference images may provide ground truth information associated with the sample input images. Thereafter, sample prediction images may be fed into the sample input images to the first machine learning model and by sequentially performing a plurality of computing operations on the sample input images. Thereafter, a consistency of the first machine learning model may be checked by comparing the sample prediction images with the sample reference images. For example, as the first machine learning model is trained, a plurality of weights included in the first machine learning model may be updated.

When the consistency of the first machine learning model does not reach a target consistency, e.g., when an error value of the trained first machine learning model is greater than a reference value, the first machine learning model may be re-trained. When the consistency of the first machine learning model reaches the target consistency, e.g., when the error value of the first machine learning model is smaller than or equal to the reference value, a result of the training operation (e.g., updated weights) may be stored, and the training operation may be terminated.

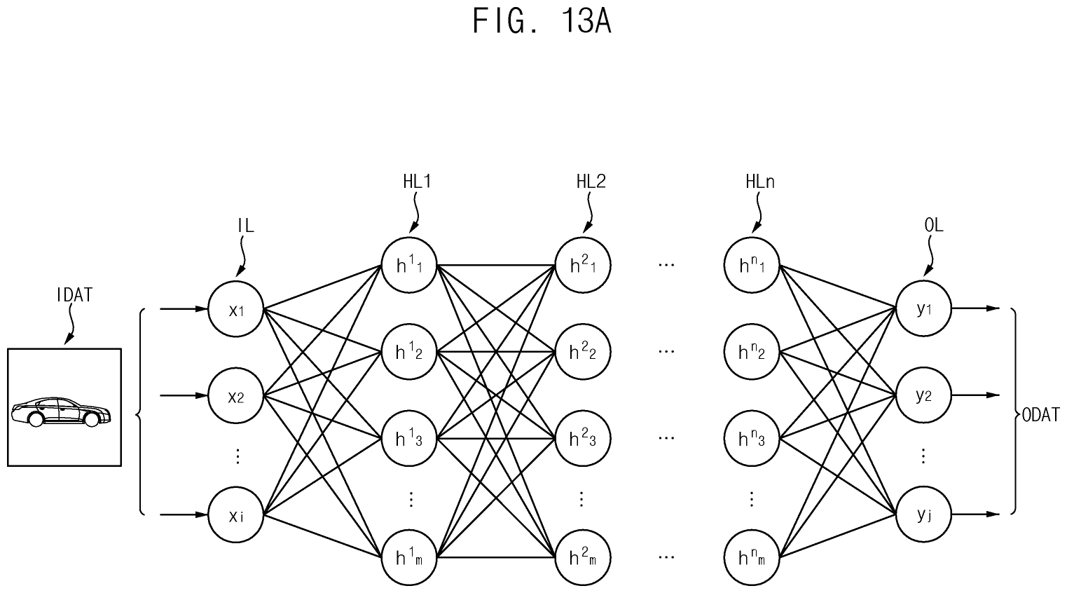

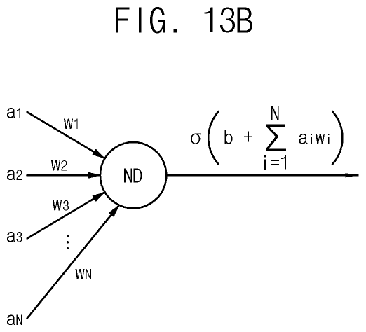

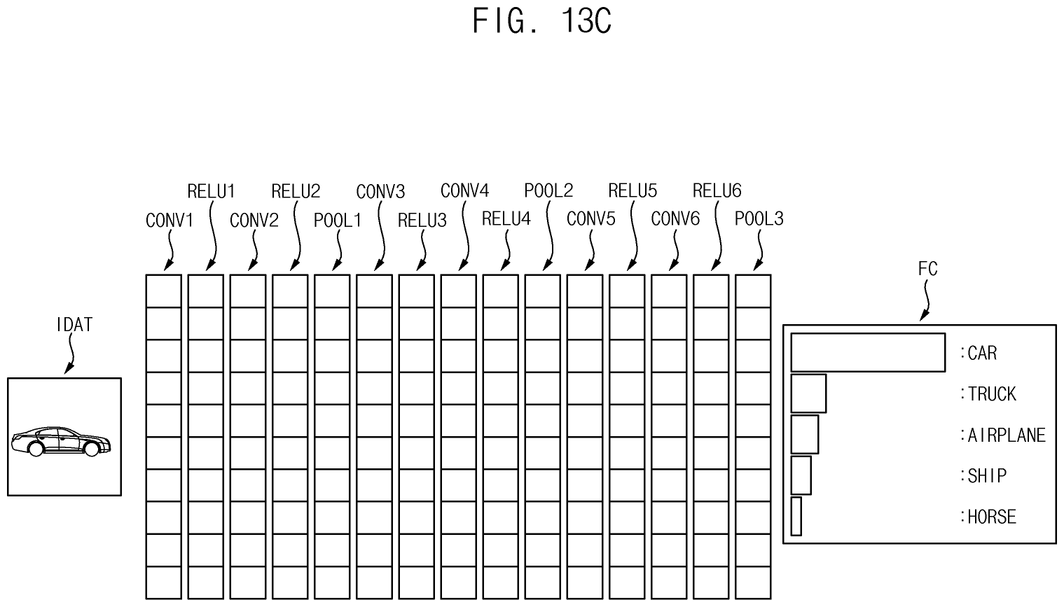

FIGS. 13A, 13B and 13C are diagrams illustrating a first machine learning model that is used in a method of correcting a layout for semiconductor process according to example embodiments. For example, the first machine learning model may be implemented using a neural network architecture.

Referring to FIG. 13A, an artificial neural network (ANN) is illustrated as an example of the first machine learning model. The general neural network may include an input layer IL, a plurality of hidden layers HL1, HL2, . . . , HLn and an output layer OL.

The input layer IL may include i input nodes such as x₁, x₂, . . . , xᵢ, where i is a natural number greater than or equal to 2. Input data (e.g., vector input data) IDAT whose length is i may be input to the input nodes x₁, x₂, . . . , xᵢ such that each element of the input data IDAT is input to a respective one of the input nodes x₁, x₂, . . . , xᵢ. The input data IDAT may include information associated with the various features of the different classes to be categorized.

The plurality of hidden layers HL1, HL2, . . . , HLn may include n hidden layers, where n is a natural number greater than or equal to 2, and may include a plurality of hidden nodes such as h¹₁, h¹₂, h¹₃, . . . , h¹ₘ, h²₁, h²₂, h²₃, . . . , h²ₘ, hⁿ₁, hⁿ₂, hⁿ₃, . . . , hⁿₘ. For example, the hidden layer HL1 may include m hidden nodes h¹₁, h¹₂, h¹₃, . . . , h¹ₘ, the hidden layer HL2 may include m hidden nodes h²₁, h²₂, h²₃, . . . , h²ₘ, and the hidden layer HLn may include m hidden nodes hⁿ₁, hⁿ₂, hⁿ₃, . . . , hⁿₘ, where m is a natural number greater than or equal to 2.

The output layer OL may include j output nodes y₁, y₂, . . . , yⱼ, where j is a natural number greater than or equal to 2. Each of the output nodes y₁, y₂, . . . , yⱼ may correspond to a respective one of classes to be categorized. The output layer OL may generate output values (e.g., class scores or numerical output such as a regression variable) or output data ODAT associated with the input data IDAT for each of the classes. In some example embodiments, the output layer OL may be a fully connected layer and may indicate, for example, a probability that the input data IDAT corresponds to a car. A fully connected layer is a type of layer in a neural network where each neuron in the layer is connected to every neuron in a previous layer. For example, in a fully connected layer, the output of each neuron may be computed by a weighted sum of the inputs from all neurons in the previous layer, followed by an application of a non-linear activation function. In some examples, the weights in the fully connected layer are learned during the training process using backpropagation.

A structure of the neural network illustrated in FIG. 13A may be represented by information on connections between nodes illustrated as lines, and a weighted value assigned to each branch, which is not illustrated. In some examples, nodes of different layers may be fully connected. In some examples, nodes of different layers may be partially connected. In some neural network models, such as unrestricted Boltzmann machines, at least some nodes within a single layer may be connected to other nodes within the same layer, in addition to or instead of being connected to nodes in other layers.

Each node (e.g., the node h¹₁) may receive an output of a previous node (e.g., the node x₁), may perform a computing operation on the received output, and may output a result as an output to a next node (e.g., the node h²₁). Each node may calculate a value to be output by applying the input to a specific function, e.g., a nonlinear function. This function may be called the activation function for the node.

In some example embodiments, the structure of the neural network is predetermined, and the weighted values for the connections between the nodes are updated during the training process by using sample data with ground truth answer (also referred to as a “label”). For example, this label indicates the class to which the data corresponding to a sample input belongs. By using this sample data, the neural network is trained to correctly classify new data inputs that it has not seen before. The data with the sample answer may be referred to as “training data”, and a process of determining the weighted values may be referred to as “training”. The neural network “learns” to associate the data with corresponding labels during the training process. A group of an independently trainable neural network structure and the weighted values that have been trained using an algorithm may be referred to as a “model”, and a process of predicting, by the model with the determined weighted values, which class new input data belongs to, and then outputting the predicted value, may be referred to as a “testing” process or operating the neural network in inference mode.

Referring to FIG. 13B, an example of an operation (e.g., computation or calculation) performed by one node ND included in the neural network of FIG. 13A is illustrated in detail.

Based on N inputs a₁, a₂, a₃, . . . , a_{N} provided to the node ND, where N is a natural number greater than or equal to two, the node ND may multiply the N inputs a₁ to a_{N} and corresponding N weights w₁, w₂, w₃, . . . , w_{N}, respectively. The node ND then may sum up N values obtained by the multiplication, add an offset “b” to a summed value, and generate one output value (e.g., “z”) by applying a value to which the offset “b” is added to a specific function “σ”.

In some example embodiments and as illustrated in FIG. 13B, one layer included in the neural network illustrated in FIG. 13A may include M nodes ND, where M is a natural number greater than or equal to two, and output values of the one layer may be obtained by Equation 1.

W*A=Z [Equation 1]

In Equation 1, “W” denotes a weight set including weights for all connections included in the one layer, and may be implemented in an M*N matrix form. “A” denotes an input set including the N inputs a₁ to a_{N} received by the one layer, and may be implemented in an N*1 matrix form. “Z” denotes an output set including M outputs z₁, z₂, z₃, . . . , z_{M} output from the one layer, and may be implemented in an M*1 matrix form.

According to some embodiments, a convolutional neural network (CNN) may be used to process the input image data (or input sound data) when the input image data, for example, is not of a fixed size or it is computationally expensive to train on large images. CNN may be implemented by combining the filtering technique with the general neural network, has been researched such that a two-dimensional image, as an example of the input image data, is efficiently trained by the convolutional neural network.

Referring to FIG. 13C, a convolutional neural network is illustrated as an example of the first machine learning model. The convolutional neural network may include a plurality of layers CONV1, RELU1, CONV2, RELU2, POOL1, CONV3, RELU3, CONV4, RELU4, POOL2, CONV5, RELU5, CONV6, RELU6, POOL3 and FC. Here, “CONV” denotes a convolutional layer, “RELU” denotes a rectified linear unit layer or activation function, “POOL” denotes a pooling layer, and “FC” denotes a fully-connected layer. A rectified linear unit layer refers to an activation function commonly which returns the input if it is positive, and zero otherwise. A pooling layer refers to a layer that reduces the spatial dimensionality of the input by down-sampling. For example, the down-sampling operation may include max pooling, which selects the maximum value within a rectangular window, average pooling, which calculates the average value of each non-overlapping subregion of the input, and L2-norm pooling, which calculates the L2-norm (Euclidean norm) of each non-overlapping subregion of the input.

In CNN, each layer of the convolutional neural network may have three dimensions of a width, a height and a depth, and thus data that is input to each layer may be volume data having three dimensions of a width, a height and a depth. For example, if an input image in FIG. 13C has a size of 32 widths (e.g., 32 pixels) and 32 heights and three color channels R, G and B, input data IDAT corresponding to the input image may have a size of 32*32*3. The input data IDAT in FIG. 13C may be referred to as input volume data or input activation volume.

According to some embodiments, in the image processing operation of a CNN, each of the convolutional layers CONV1, CONV2, CONV3, CONV4, CONV5 and CONV6 may perform a convolutional operation on input volume data. In an image processing operation, the convolutional operation represents an operation in which image data is processed based on a mask with weighted values and an output value is obtained by multiplying input values with the corresponding weighted values and summing up the results. The mask may be referred to as a filter, a window, or a kernel. For example, the mask may be a matrix of weighted values that is applied to the input data during the convolutional operation.

Parameters of each convolutional layer may include a set of filters that are learnable. Every filter may be small spatially (along a width and a height), but may extend through the full depth of an input volume. For example, during the forward pass, each filter may be slid (e.g., convolved) across the width and height of the input volume, and dot products may be computed between the entries of the filter and the input at any position. As the filter is slid over the width and height of the input volume, a two-dimensional activation map corresponding to responses of that filter at every spatial position may be generated. As a result, an output volume may be generated by stacking these activation maps along the depth dimension. For example, if input volume data having a size of 32*32*3 passes through the convolutional layer CONV1 having four filters with zero-padding, output volume data of the convolutional layer CONV1 may have a size of 32*32*12 (e.g., a depth of volume data increases). Zero-padding refers to adding extra rows and columns of zeros to the edges of an image, increasing the size of an image to match the input size required by the convolutional layer CONV1 or other image processing algorithm.

Each of the RELU layers RELU1, RELU2, RELU3, RELU4, RELU5 and RELU6 may perform a rectified linear unit (RELU) operation that corresponds to an activation function defined by, e.g., a function f(x)=max(0, x), wherein an output is zero for all negative input x. For example, if input volume data having a size of 32*32*12 passes through the RELU layer RELU1 to perform the rectified linear unit operation, output volume data of the RELU layer RELU1 may have a size of 32*32*12 (e.g., a size of volume data is maintained).

Each of the pooling layers POOL1, POOL2 and POOL3 may perform a down-sampling operation on input volume data along spatial dimensions of width and height. The input values are divided into non-overlapping regions, and a single output value is generated for each region based on a pooling method, such as maximum pooling or average pooling. For example, four input values arranged in a 2*2 matrix formation may be converted into one output value based on a 2*2 filter. For example, a maximum value of four input values arranged in a 2*2 matrix formation may be selected based on 2*2 maximum pooling. For example, an average value of four input values arranged in a 2*2 matrix formation may be obtained based on 2*2 average pooling. For example, if input volume data having a size of 32*32*12 passes through the pooling layer POOL1 having a 2*2 filter, output volume data of the pooling layer POOL1 may have a size of 16*16*12 (e.g., a width and a height of volume data decreases, and a depth of volume data is maintained).

For example, convolutional layers may be arranged in a repeated manner in the convolutional neural network, and the pooling layer may be periodically inserted in the convolutional neural network, thereby reducing a spatial size of an image and extracting characteristics from the image.

The output layer or fully-connected layer FC may output results (e.g., class scores) of the input volume data IDAT for each of the classes. For example, the input volume data IDAT corresponding to the two-dimensional image may be converted into a one-dimensional matrix or vector, which may be referred to as an embedding, as the convolutional operation and the down-sampling operation are repeated. For example, an embedding may be a representation of an input as a vector in a high-dimensional space. For example, the embedding may be created by assigning numerical values to each element of the input, such that semantically similar input may have similar numerical values. For example, the fully-connected layer FC may indicate probabilities that the input volume data IDAT corresponds to a car, a truck, an airplane, a ship and a horse.

The types and number of layers included in the convolutional neural network may not be limited to an example described with reference to FIG. 13C and may be variously determined according to example embodiments. In addition, the convolutional neural network may further include other layers such as a softmax layer for converting score values corresponding to predicted results into probability values, a bias adding layer for adding at least one bias, or the like. The bias may also be incorporated into the activation function.

However, example embodiments may not be limited to the above-described neural networks. For example, the first machine learning model may be implemented by using other neural networks such as generative adversarial network (GAN), region with convolutional neural network (R-CNN), region proposal network (RPN), recurrent neural network (RNN), stacking-based deep neural network (S-DNN), state-space dynamic neural network (S-SDNN), deconvolution network, deep belief network (DBN), restricted Boltzman machine (RBM), fully-convolutional network, long short-term memory (LSTM) network, or the like.

FIG. 14 is a flowchart illustrating an example of training at least one of a first machine learning model and a second machine learning model in FIG. 11.

Referring to FIGS. 11 and 14, during the training of at least one of the first machine learning model and the second machine learning model (operation S500), sample input features may be acquired (operation S530), and the second machine learning model may be trained based on the sample input features (operation S540). Operations S530 and S540 may be similar to operations S510 and S520 in FIG. 12, respectively. For example, during the training of the second machine learning model is trained, the sample input features and corresponding sample reference features may be obtained together, and the corresponding sample reference features may represent ground truth information associated with the sample input features. Thereafter, sample prediction features may be generated by feeding the sample input features into the second machine learning model and by sequentially performing a plurality of computing operations on the sample input features. Thereafter, a consistency of the second machine learning model may be checked by comparing the sample prediction features with the sample reference features.

For example, the sample input features may include horizontal features and vertical features. The horizontal features may correspond to the arrangement of layout patterns and their effect on process patterns, while the vertical features may correspond to the effect of lower-level structures in a semiconductor device on process patterns.

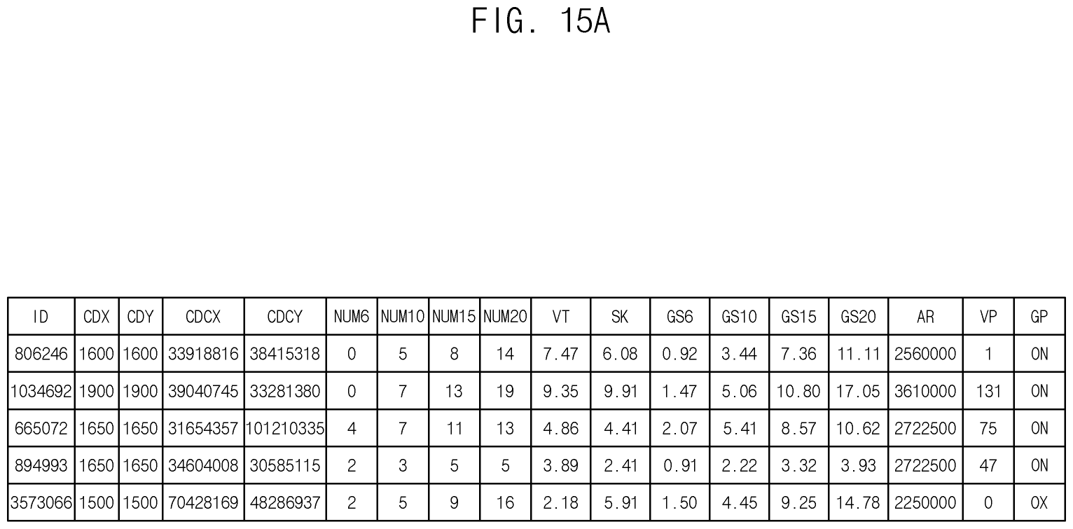

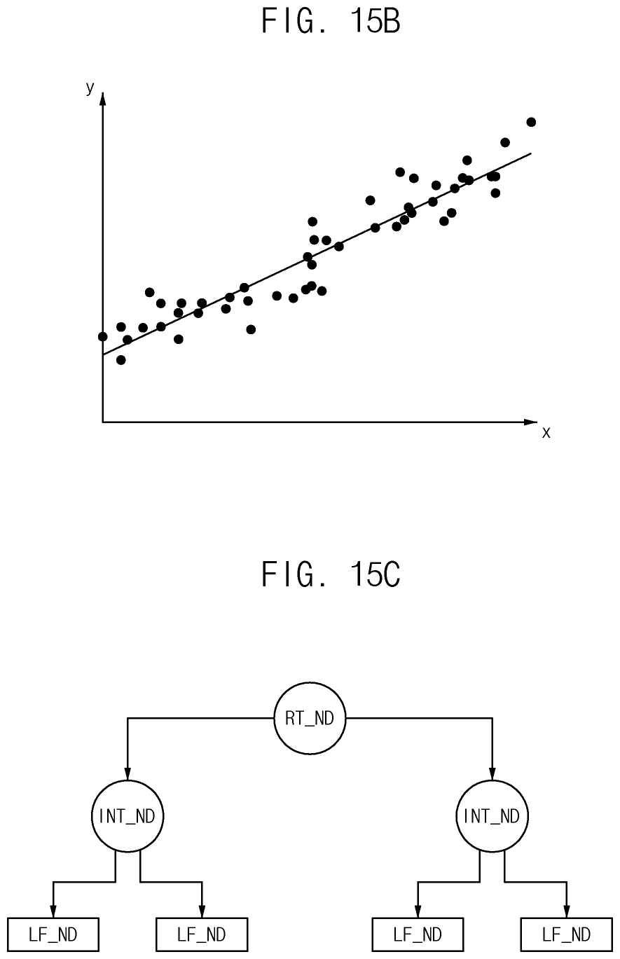

FIGS. 15A, 15B and 15C are diagrams illustrating a second machine learning model that is used in a method of correcting a layout for semiconductor process according to example embodiments.

Referring to FIG. 15A, an example of features that are used to train the second machine learning model is illustrated.

In FIG. 15A, “ID” represents identification numbers for each pattern, “CDX” and “CDY” represent sizes of the patterns in a row direction and a column direction, respectively, “CDCX” and “CDCY” represent positions of the patterns in the row direction and the column direction, respectively, and “AR” represents an area of the patterns. For example, CDX, CDY, CDCX, CDCY and AR may correspond to the dimensional horizontal features of the patterns themselves.

In addition, in FIG. 15A, “NUMi”, where i is a natural number, represents the number of neighboring patterns in an influence range capable of affecting each pattern and includes information on density of the patterns, “GSi” represents information on distance of the neighboring patterns, “VT” represents an effect of an electric field applied to the neighboring patterns during the etching process, and “SK” represents skew information caused during the etching process. In NUMi and GSi, the index i represents the influence range, and accordingly, the radius of the influence range may be increased as the index i is increased. For example, NUMi, GSi, VT and SK may correspond to the horizontal features representing effects of the neighboring patterns.

Further, in FIG. 15A, “VP” represents the position information, for example, a vertical position at which a composition of the lower structure is varied with respect to each of the layout patterns. “GR” represents group information indicating a composition forming the lower structure with respect to each of the layout patterns. For example, VP and GR may correspond to the vertical features representing an effect of a lower structure on the process patterns.

Referring to FIG. 15B, a linear regression model is illustrated as an example of the second machine learning model.

Linear regression refers to a linear approach for modelling the relationship between a scalar response (or dependent variable) “y” and one or more explanatory variables (or independent variables) “x”. In linear regression, the relationships are modeled using linear predictor functions whose unknown model parameters are estimated from the data. The linear regression model is a mathematical representation of this relationship, typically expressed as an equation of a straight line, with the dependent variable as the output “y” and the independent variable(s) as the input “x”. For example, if the goal is error reduction in prediction or forecasting, linear regression can be used to fit a predictive model to an observed data set of values of the response and explanatory variables.

In FIG. 15B, “x” represents the sample input features, “y” represents the sample reference features, and a function illustrated as a straight line represents a linear prediction function or a linear regression model.

However, embodiments of the present disclosure are not limited thereto. For example, a first inference may be performed on the sample input features using the linear regression, and a second inference may be performed on a result of the first inference using non-linear regression.

Referring to FIG. 15C, a decision tree model is illustrated as an example of the second machine learning model.

A decision tree has a hierarchical, tree-shaped structure, which includes a root node RT_ND, branches, internal nodes (or decision nodes) INT_ND and leaf nodes (or terminal nodes) LF_ND. The decision tree starts with the root node RT_ND, which does not have incoming branches. The outgoing branches from the root node RT_ND then feed into the internal nodes INT_ND. Based on the available features, both node types conduct evaluations to form homogenous subsets, which are denoted by the leaf nodes LF_ND. The leaf nodes LF_ND represent all the possible outcomes within the dataset.

However, example embodiments may not be limited to the above-described models. For example, the second machine learning model may be implemented by various other forms of machine learning models, such as, for example, association rule learning, genetic algorithm, inductive learning, support vector machine (SVM), cluster analysis, reinforcement learning, logistic regression, statistical clustering, Bayesian classification, dimensionality reduction such as principal component analysis, and expert systems; or combinations thereof, including ensembles such as random forests.

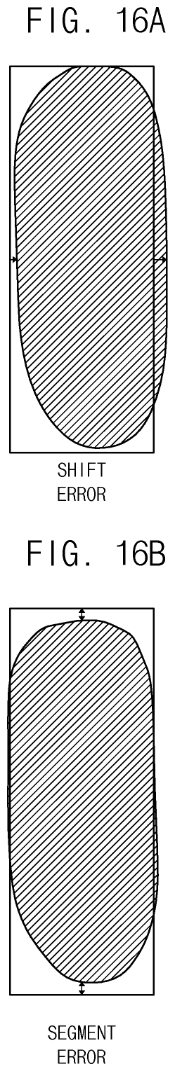

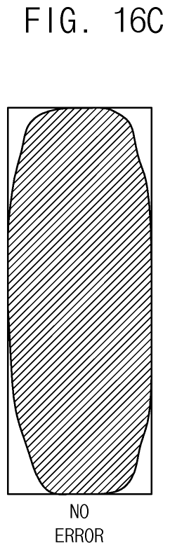

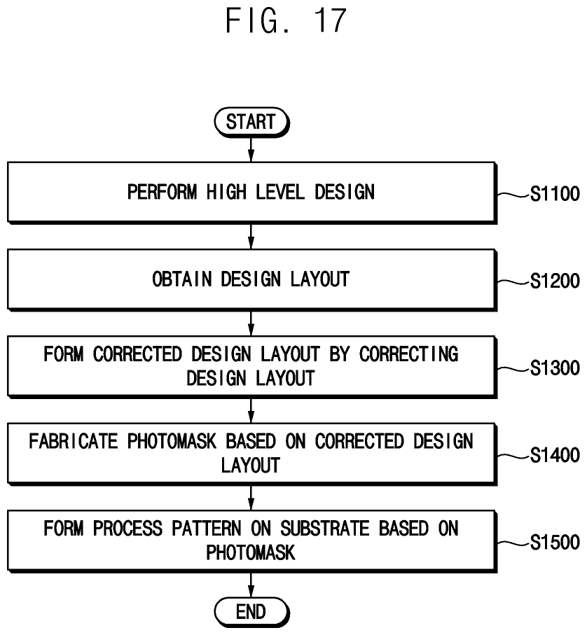

FIGS. 16A, 16B and 16C are diagrams illustrating a method of correcting a layout for semiconductor process according to example embodiments.

Referring to FIG. 16A, when only the feature-based machine learning model is implemented, shift errors may occur. In some examples, pattern placement errors may increase.

Referring to FIG. 16B, when only the image-based machine learning model is implemented, segment errors (or targeting errors) may occur. In some examples, edge placement errors may increase.

Referring to FIG. 16C, when both the image-based machine learning model and the feature-based machine learning model are implemented according to example embodiments, both the shift errors and the segment errors may be prevented, and the accuracy of the layout correction may be increased.

Although example embodiments are described based on that the corrected design layout is obtained using two different machine learning models, embodiments of the present disclosure are not limited thereto. For example, the corrected design layout may be obtained using three or more different machine learning models.

FIG. 17 is a flowchart illustrating a method of manufacturing a semiconductor device according to example embodiments.

Referring to FIG. 17, in a method of manufacturing a semiconductor device according to example embodiments, a high-level design process of the semiconductor device is performed (operation S1100). For example, in the high-level design process, an integrated circuit to be designed may be described in terms of high-level computer language (e.g., C language). Circuits designed by the high-level design process may be more concretely described by a register transfer level (RTL) coding or a simulation. In addition, codes generated by the RTL coding may be converted into a netlist, and the results may be combined to create an entire semiconductor device. The combined schematic circuit may be verified by a simulation tool. In some example embodiments, an adjusting operation may be further performed based on a result of the verification operation.

A design layout including a layout pattern for semiconductor process to form a process pattern of the semiconductor device is obtained (operation S1200). In some examples, a layout design process may be performed to implement a logically completed semiconductor device that has been verified on a silicon substrate. For example, the layout design process may be performed based on the schematic circuit prepared in the high-level design process or the netlist corresponding thereto. The layout design process may include a routing operation of placing and connecting various standard cells that are provided from a cell library, based on a predetermined design rule.

A cell library for the layout design process may contain information related to operation, speed, and power consumption of the standard cells. In some example embodiments, the cell library for representing a layout of a circuit having a specific gate level may be defined in a layout design tool (e.g., the system 1000 of FIG. 2). Here, the layout may be prepared to define or describe shapes and sizes of patterns constituting transistors and metal interconnection lines, which will then be physically implemented or formed on a silicon substrate. For example, layout patterns (e.g., PMOS, NMOS, N-WELL, gate electrodes, and metal interconnection lines thereon) may be suitably disposed to actually form an inverter circuit on a silicon substrate. For this, at least one of inverters defined in the cell library may be selected.

In addition, the routing operation may be performed on selected and disposed standard cells. In some examples, the routing operation may be performed on the selected and disposed standard cells to connect them to upper interconnection lines. By the routing operation, the standard cells may be electrically connected to each other to meet a design requirement. These operations (e.g., operations S1100 and S1200) may be automatically or manually performed in the layout design tool. In some example embodiments, an operation of placing and routing the standard cells may be automatically performed by an additional place & routing tool.

After the routing operation, a verification operation may be performed on the layout to check whether there is a portion violating the given design rule. In some example embodiments, the verification operation may include evaluating verification items, such as a design rule check (DRC), an electrical rule check (ERC), and a layout vs schematic (LVS). DRC may be used to evaluate whether the layout meets the given design rule. ERC may be used to evaluate whether there is an issue of electrical disconnection in the layout. LVS may be used to evaluate whether the layout is prepared to coincide with the gate-level netlist.

A corrected design layout is formed or generated by correcting the design layout (operation S1300). Operation S1300 may include using the method of correcting the layout for the semiconductor process according to example embodiments described with reference to FIGS. 1 through 16C.

A photomask is fabricated based on the corrected design layout (operation S1400). For example, the layout pattern data may be used to pattern a chromium layer provided on a glass substrate, in order to fabricate or manufacture the photomask.

The process pattern is formed on a substrate using the photomask (operation S1500), and thus the semiconductor device is manufactured. For example, various exposure processes and etching processes may be repeated in the manufacture of the semiconductor device using the photomask. By these processes, shapes of patterns obtained in the layout design process may be sequentially formed on a silicon substrate.

The example embodiments may be implemented to designing and manufacturing processes of the semiconductor devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments of the present disclosure and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments of the present disclosure as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of correcting a layout for semiconductor process, the method comprising:
receiving a design layout including a layout pattern for the semiconductor process to form a process pattern of a semiconductor device, wherein the design layout comprises a pixel-based image associated with the layout pattern and edge information associated with the layout pattern;
performing a first layout correction operation on the design layout using a first machine learning model that takes the pixel-based image as input;
performing a second layout correction operation on the design layout using a second machine learning model different from the first machine learning model that takes the edge information as input; and
obtaining a corrected design layout including a corrected layout pattern corresponding to the layout pattern based on a result of the first layout correction operation and a result of the second layout correction operation.

2. The method of claim 1, wherein the first machine learning model comprises an image-based machine learning model.

3. The method of claim 1, wherein the first layout correction operation comprises a shift correction adjusting a position of the layout pattern.

4. The method of claim 1,
wherein the second machine learning model is a feature-based machine learning model.

5. The method of claim 1, wherein the second layout correction operation comprises a segment correction adjusting a position of a segment that is a part of an edge of the layout pattern.

6. The method of claim 1, wherein performing the first layout correction operation includes:
predicting the process pattern that is to be obtained by a current state of the layout pattern using the first machine learning model to obtain a first predicted process pattern; and
shifting a position of the layout pattern by comparing the first predicted process pattern with a reference layout pattern.

7. The method of claim 6, wherein performing the first layout correction operation further includes:
calculating a first error value by comparing the first predicted process pattern with the reference layout pattern,
wherein, in response to the first error value being greater than or equal to a first reference value, the position of the layout pattern is re-shifted, and
wherein, in response to the first error value being smaller than the first reference value, the position of the layout pattern is maintained.

8. The method of claim 7, wherein the first error value is a pattern placement error (PPE) value that represents a difference between a centroid of the first predicted process pattern and a centroid of the reference layout pattern.

9. The method of claim 7, wherein performing the first layout correction operation further includes:
calculating a second error value by comparing the first predicted process pattern with the reference layout pattern, the second error value being different from the first error value, and
wherein, in response to the second error value being greater than or equal to a second reference value, the second layout correction operation is performed.

10. The method of claim 9, wherein the second error value is an edge placement error (EPE) value that represents a difference between an edge of the first predicted process pattern and an edge of the reference layout pattern.

11. The method of claim 9, wherein performing the second layout correction operation includes:
predicting the process pattern that is to be obtained by the current state of the layout pattern using the second machine learning model to obtain a second predicted process pattern; and
correcting a position of a segment that is a part of an edge of the layout pattern by comparing the second predicted process pattern with the reference layout pattern.

12. The method of claim 11, wherein performing the second layout correction operation further includes:
re-calculating the second error value by comparing the second predicted process pattern with the reference layout pattern,
wherein, in response to the second error value being greater than or equal to the second reference value, the position of the segment of the layout pattern is re-corrected, and
wherein, in response to the second error value being smaller than the second reference value, the position of the segment of the layout pattern is maintained.

13. The method of claim 12, wherein performing the second layout correction operation further includes:
re-calculating the first error value by comparing the second predicted process pattern with the reference layout pattern, and
wherein, in response to the first error value being greater than or equal to the first reference value, the first layout correction operation is re-performed.

14. The method of claim 13, wherein the first layout correction operation and the second layout correction operation are performed alternately and repeatedly until the first error value becomes smaller than the first reference value and the second error value becomes smaller than the second reference value.

15. The method of claim 1, wherein the design layout is corrected by performing process proximity correction (PPC) or optical proximity correction (OPC) using the first machine learning model and the second machine learning model.

16. The method of claim 1, further comprising:
training at least one of the first machine learning model and the second machine learning model.

17. A semiconductor device manufactured using the method of claim 1.

18. A method of manufacturing a semiconductor device, the method comprising:
obtaining a design layout including a layout pattern for semiconductor process to form a process pattern of the semiconductor device;
forming a corrected design layout by correcting the design layout;
fabricating a photomask based on the corrected design layout; and
forming the process pattern on a substrate using the photomask,
wherein forming the corrected design layout includes:
receiving the design layout;
performing a first layout correction operation on the design layout using a first machine learning model;
performing a second layout correction operation on the design layout using a second machine learning model different from the first machine learning model; and
obtaining the corrected design layout including a corrected layout pattern corresponding to the layout pattern based on a result of the first layout correction operation and a result of the second layout correction operation.

19. A semiconductor device manufactured by the method of claim 18.

20. A layout correction system comprising:
at least one processor; and
a non-transitory computer readable medium configured to store program code executed by the at least one processor to form a corrected design layout by correcting a design layout, the design layout including a layout pattern for semiconductor process to form a process pattern of a semiconductor device,
wherein the at least one processor is configured, by executing the program code:
to receive the design layout;
to perform a first layout correction operation on the design layout using a first machine learning model, wherein the first layout correction operation comprises a shift correction;
to perform a second layout correction operation on the design layout using a second machine learning model different from the first machine learning model, wherein the second layout correction operation comprises a segment correction; and
to obtain the corrected design layout including a corrected layout pattern corresponding to the layout pattern based on a result of the first layout correction operation and a result of the second layout correction operation.
